(19) United States
(12) Patent Application Publication
(10) Pub. No.: US 2015/0235715 A1
(43) Pub. Date: Aug. 20, 2015

(54) STACKED SEMICONDUCTOR MEMORY APPARATUS AND TEST CIRCUIT THEREFOR

(71) Applicant: SK hynix Inc., Icheon-si Gyeonggi-do (KR)

(72) Inventor: Jang Hwan CHO, Icheon-si Gyeonggi-do (KR)

(73) Assignee: SK hynix Inc., Icheon-si Gyeonggi-do (KR)

(21) Appl. No.: 14/279,847

(22) Filed: May 16, 2014

(30) Foreign Application Priority Data
Feb. 17, 2014 (KR) 10-2014-0017725

(51) Int. Cl. G11C 29/10

(52) U.S. Cl. CPC G11C 29/10

(57) ABSTRACT

A stacked semiconductor memory apparatus includes a memory module including a plurality of memory chips; and a logic circuit block with the memory module stacked thereon, configured to be electrically coupled with an interface substrate through a first terminal group and a second terminal group and to communicate with a controller, and to include a test circuit that receives a first test signal through the first terminal group from the controller and outputs the first test signal through the second terminal group in a test mode.

### CROSS-REFERENCES TO RELATED APPLICATION

The present application claims priority under 35 U.S.C. §119(a) to Korean application number 10-2014-0017725, filed on Feb. 17, 2014, in the Korean Intellectual Property Office, which is incorporated herein by reference in its entirety.

### BACKGROUND

1. Technical Field

Various embodiments relate to a semiconductor apparatus, and more particularly, to a stacked semiconductor memory apparatus and a test circuit therefore.

2. Related Art

As the size of a portable electronic appliance decreases, a semiconductor package disposed therein gradually trends toward miniaturization and light weight. Conversely, a memory chip which is built in a semiconductor package is required to be manufactured to have high capacity.

### SUMMARY

In an embodiment, a stacked semiconductor memory apparatus may include a memory module including a plurality of memory chips. The stacked semiconductor memory apparatus may also include a logic circuit block with the memory module stacked thereon, and configured to be electrically coupled with an interface substrate through a first terminal group and a second terminal group and to communicate with a controller. The stacked semiconductor memory apparatus may also include a test circuit that receives a first test signal through the first terminal group from the controller and outputs the first test signal through the second terminal group in a test mode.

In an embodiment, a test circuit of a stacked semiconductor memory apparatus may include a first terminal group configured to be provided with a first test signal provided from a controller. The stacked semiconductor memory apparatus may also include a first signal transmission block configured to transmit the first test signal applied to the first terminal group through a first path or a second path in response to a test mode signal and a control signal. Further, the stacked semiconductor memory apparatus may include a second terminal group configured to output the first test signal transmitted through the first path or the second path.

In an embodiment, a stacked semiconductor memory apparatus includes a memory module including a plurality of stacked memory chips. The stacked semiconductor memory apparatus may also include a logic circuit block configured to be electrically coupled with an interface substrate through a first terminal group and a second terminal group and with the memory module stacked thereon. In addition, the logic circuit block may be configured to perform a test for the memory module using the second terminal group.

### BRIEF DESCRIPTION OF THE DRAWINGS

FIG. 1 is a configuration diagram of a stacked semiconductor memory apparatus in accordance with an embodiment.

FIG. 2 is a configuration diagram of a test circuit in accordance with an embodiment.

FIG. 3 is a diagram showing an embodiment of the test circuit shown in FIG. 2.

FIG. 4 is a diagram showing an embodiment of the signal transmission block shown in FIG. 3.

FIG. 5 is a configuration diagram of a test circuit in accordance with an embodiment.

FIG. 6 is a diagram showing an embodiment of the test circuit shown in FIG. 5.

FIG. 7 is a diagram showing embodiments of the first signal transmission block and the second signal transmission block shown in FIG. 6.

FIG. 8 illustrates a block diagram of a system employing a memory controller circuit in accordance with an embodiment of the invention.

### DETAILED DESCRIPTION

Various embodiments and examples of a semiconductor memory apparatus will be described below with reference to various figures. While a single chip package memory is realized by packaging one memory chip, recently, a multi-chip package memory is manufactured by stacking a plurality of memory chips to meet the demand for miniaturization, light weight and high capacity. Recently, a plurality of chips have been electrically coupled using through-silicon vias (TSVs). Stacked memory chips may be electrically coupled to a controller and an external device through terminals such as bumps. Under this situation, a way to verify the reliability of terminals to electrically couple stacked memory devices to a controller or an external device is needed.

Referring to FIG. 1, a configuration diagram of a stacked semiconductor memory apparatus in accordance with an embodiment is illustrated.

The stacked semiconductor memory apparatus 10 shown in FIG. 1 may include a logic circuit block 11, a memory module 12 in which a plurality of semiconductor chips n to 1 are stacked. The semiconductor memory apparatus 10 may also include a controller 13, an interface substrate 14, a first terminal group 15, a second terminal group 16, a third terminal group 17, a fourth terminal group 18, and an external connection terminal group 19.

In an embodiment, the first to fourth terminals groups 15, 16, 17 and 18 are internal connection terminal groups. In addition, the first to fourth terminal groups 15 to 18 may be constituted by, but not limited to, micro bumps. The external connection terminal group 19 may be constituted by, and also not limited to, flip chip bumps.

The logic circuit block 11 may be disposed on one part of the top surface of the interface substrate 14. The logic circuit block 11 may be electrically coupled with the interface substrate 14 through the first terminal group 15 and the second terminal group 16. The first terminal group 15 may be a terminal group electrically coupled with the controller 13 through the interface substrate 14. The second terminal group 16 may be direct access balls (DABs) which are electrically coupled with a first external connection terminal group 19A through the interface substrate 14. After stacking the memory module 12 on the logic circuit block 11 and before or after mounting a resultant structure to the interface substrate 14, a test for the memory module 12 may be performed. The test may be performed using the second terminal group 16.

The memory module 12 may be configured on the top surface of the logic circuit block 11.

The controller 13 may be disposed on the other part of the top surface of the interface substrate 14. The controller 13 may also be electrically coupled with the interface substrate 14 through the third terminal group 17 and the fourth terminal group 18. The third terminal group 17 may communicate with the first terminal group 15 through the interface substrate 14. The fourth terminal group 18 may be electrically coupled with a second external connection terminal group 19B through the interface substrate 14.

The logic circuit block 11 may comprise a test circuit 11A.

In a test mode, the stacked semiconductor memory apparatus 10 may be electrically coupled with a test board (not shown) through the external connection terminal group 19. The signal outputted from the test circuit 11A is provided to the test board through the external connection terminal group 19.

In an embodiment, the test circuit 11A may receive the signal provided from the controller 13 in the test mode. The signal may be provided through the third terminal group 17, the interface substrate 14 and the first terminal group 15. The test circuit 11A may output the signal to the first external connection terminal group 19A through the second terminal group 16 and the interface substrate 14. Through such a signal transmission process, a reliability test for the first terminal group 15 may be performed. In the alternative a reliability test for a main input/output line (MIO) may be performed.

In an embodiment, where a direct memory access signal (SEL_DMA) is enabled in the test mode, the test circuit 11A may be provided with the test signal received through any one first external connection terminal included in the first external connection terminal group 19A, through the interface substrate 14 and the second terminal group 16. The test circuit 11A may transmit the test signal to the first terminal group 15. In addition, the test circuit 14 may then output the test signal to another first external connection terminal included in the first external connection terminal group 19A, through the second terminal group 16 and the interface substrate 14. Even through such a signal transmission process, a reliability test for the first terminal group 15 may be performed. Further, in the alternative, a reliability test for the main input/output line (MIO) may be performed.

In a normal operation mode, the test circuit 11A may transmit the signal provided from the controller 13, to the memory module 12 through a transmission line 20.

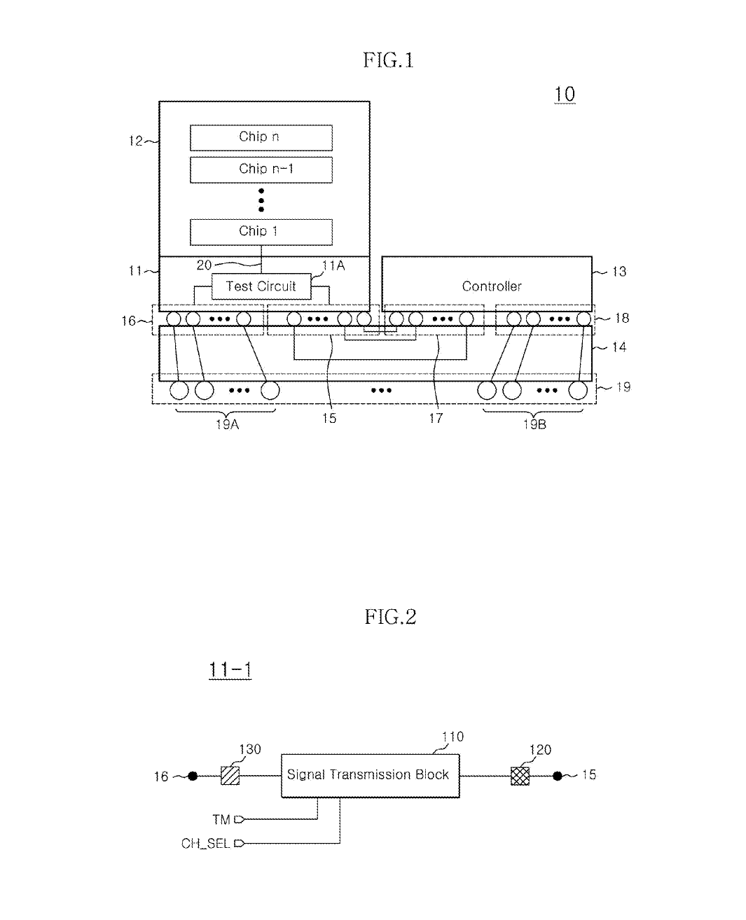

Referring to FIG. 2, a test circuit 11-1 in accordance with an embodiment may include a signal transmission block 110. The signal transmission block 110 is electrically coupled between a first pad 120 and a second pad 130. The first pad 120 is a pad electrically coupled with any one first terminal included in the first terminal group 15. The second pad 130 is a pad electrically coupled with any one second terminal included in the second terminal group 16. The signal transmission block 110 outputs the test signal received through the first pad 120, to the second pad 130 in response to a test mode signal TM and a control signal CH_SEL.

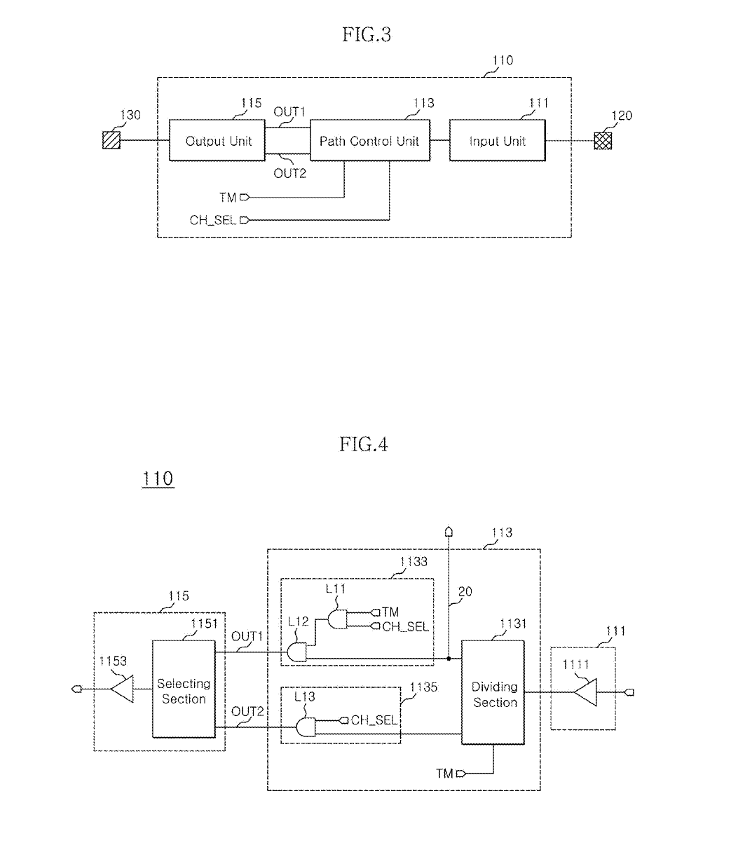

Referring to FIG. 3, an embodiment of the signal transmission block 110 may include an input unit 111, a path control unit 113, and an output unit 115.

The input unit 111 is configured to drive and output the test signal provided from the first pad 120.

The path control unit 113 is configured to output the test signal provided through the input unit 111, to a first output line OUT1 through a first path or to a second output line OUT2 through a second path, in response to the test mode signal TM and the control signal CH_SEL.

In an embodiment, the first path may be the output path of a test signal to monitor the main input/output line (MIO). In addition, the second path may be the output path of a test signal to monitor the first terminal group 15.

The output unit 115 is configured to drive and output any one of the signals of the first output line OUT1 and the second output line OUT2 to the second pad 130.

Referring to FIG. 4, a diagram showing an embodiment of the signal transmission block 110 shown in FIG. 3 is illustrated.

The input unit 111 may be configured to include a buffer section 1111 which drives and outputs the test signal provided through the first pad 120.

The path control unit 113 may be configured to include a dividing section 1131, a first path setting section 1133, and a second path setting section 1135.

The dividing section 1131 may be configured to divide the test signal provided from the input unit 111, into a plurality of test signals in response to the test mode signal TM. The dividing section 1131 may also be configured to output the plurality of test signals. In an embodiment, the dividing section 1131 may divide an input signal into two signals. The dividing section 1131 may also provide the two signals as the input signals of the first path setting section 1133 and the second path setting section 1135.

The first path setting section 1133 may be configured to transmit the test signal provided from the dividing section 1131, to the first output line OUT1 in response to the test mode signal TM and the control signal CH_SEL. The second path setting section 1135 may be configured to transmit the test signal provided from the dividing section 1131, to the second output line OUT2 in response to the control signal CH_SEL.

One output line of the dividing section 1131, electrically coupled with the first path setting section 1133, is also electrically coupled with the transmission line 20 which is electrically coupled with the memory module 12. Therefore, when transmitting a test signal through the first path setting section 1133, it is possible to monitor the state of the main input/output line (MIO). Further, by transmitting a test signal through the second path setting section 1135, it is possible to monitor the state of the first terminal group 15.

The first path setting section 1133 may be configured to include a determination part L11 which determines a test option in response to the test mode signal TM and the control signal CH_SEL. The first path setting section 1133 may also be configured to include a first output signal generation part L12 which generates a first test signal in response to the output signal of the determination part L11 and one output signal of the dividing section 1131. The first output signal generation part L12 outputs the first test signal to the first output line OUT1. The test option may include a main input/output line (MIO) test option and a first terminal group test option.

The second path setting section 1135 may be configured to include a second output signal generation part L13 which generates a second test signal in response to the other output signal of the dividing section 1131 and the control signal CH_SEL. The second output signal generation part L13 also outputs the second test signal to the second output line OUT2.

The output unit 115 may include a selecting section 1151 which selects any one of the signals of the first output line OUT1 and the second output line OUT2. The output unit 115 may also include a buffer section 1153 which drives and outputs the output signal of the selecting section 1151 to the second pad 130.

In an embodiment, where both the test mode signal TM and the control signal CH_SEL are enabled in the test mode, the output signal of the dividing section 1131 is provided to the output unit 115 through the first path setting section 1133. In addition, monitoring for the main input/output line (MIO) is implemented. Conversely, where only the control signal CH_SEL is enabled in the test mode, the output signal of the dividing section 1131 is provided to the output unit 115 through the second path setting section 1135. Further, monitoring for the first terminal group 15 is implemented.

Referring to FIG. 5, a configuration diagram of a test circuit in accordance with an embodiment is illustrated.

A test circuit 11-2 may be configured to include a first signal transmission block 110-1, and a second signal transmission block 140.

The first signal transmission block 110-1 is electrically coupled between a first pad 120 and a second pad 130-1. The first pad 120 is a pad electrically coupled with any one first terminal included in the first terminal group 15. The second pad 130-1 is a pad electrically coupled with any one second terminal 16-1 included in the second terminal group 16. The first signal transmission block 110-1 outputs the test signal received through the first pad 120, to the second pad 130-1 in response to a test mode signal TM and a control signal CH_SEL.

The second signal transmission block 140 is electrically coupled between a third pad 130-2 and the first pad 120. The third pad 130-2 is a pad electrically coupled with another second terminal 16-2 included in the second terminal group 16. The second signal transmission block 140 transmits the test signal received through the third pad 130-2, to the first pad 120 in response to the control signal CH_SEL. The signal transmitted to the first pad 120 by the second signal transmission block 140 may be outputted to the second pad 130-1 through the first signal transmission block 110-1.

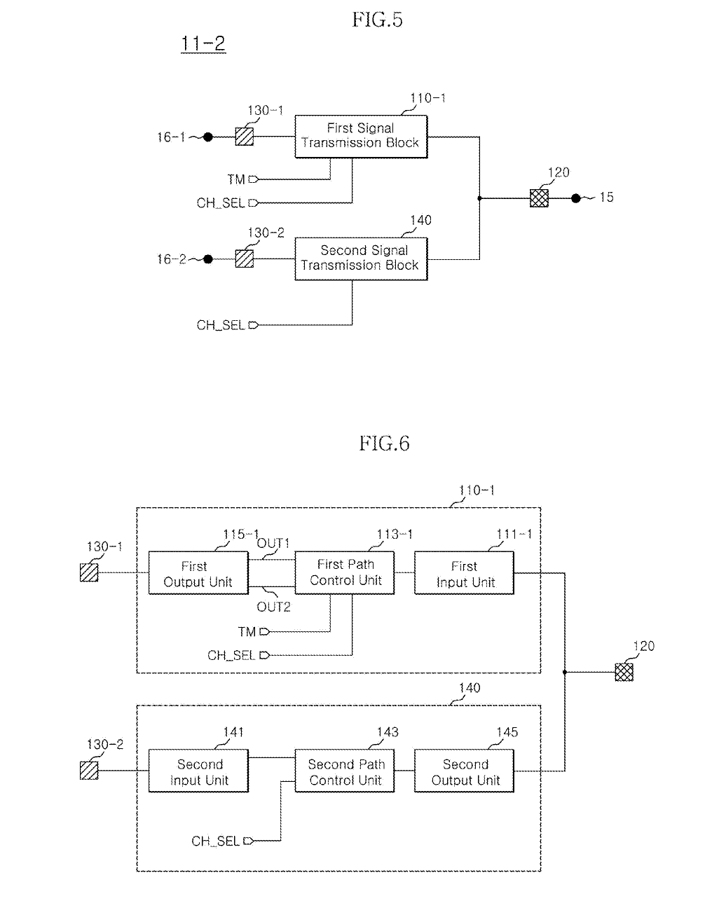

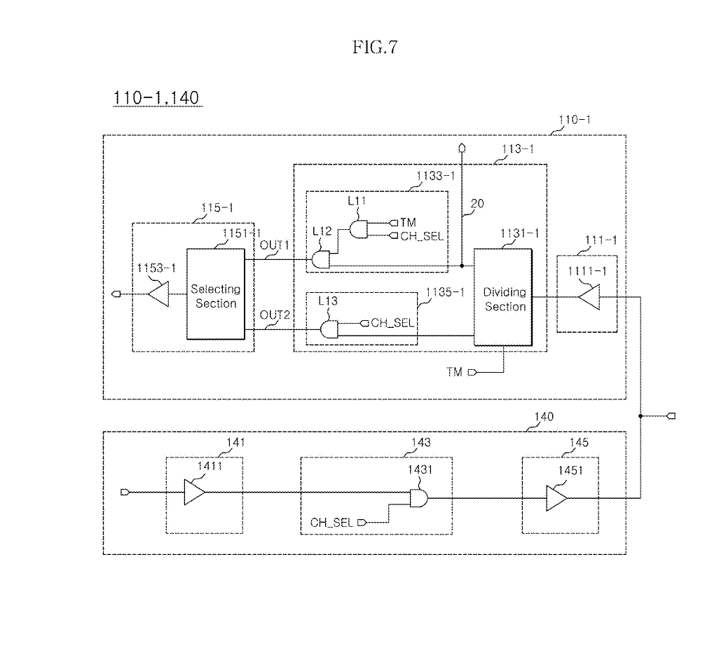

Referring to FIG. 6, a diagram showing an embodiment of the test circuit 11-2 shown in FIG. 5 is illustrated.

The first signal transmission block 110-1 may be configured to include a first input unit 111-1, a first path control unit 113-1, and a first output unit 115-1.

The first input unit 111-1 may be configured to drive and output the test signal provided from the first pad 120. The first path control unit 113-1 may be configured to output the test signal provided through the first input unit 111-1, to a first output line OUT1 through a first path or to a second output line OUT2 through a second path, in response to the test mode signal TM and the control signal CH_SEL. In an embodiment, the first path may be the output path of a test signal to monitor the main input/output line (MIO). In addition, the second path may be the output path of a test signal to monitor the first terminal group 15. The first output unit 115-1 may be configured to drive and output any one of the signals of the first output line OUT1 and the second output line OUT2, to the second pad 130-1.

The second signal transmission block 140 may be configured to include a second input unit 141, a second path control unit 143, and a second output unit 145.

The second input unit 141 may be configured to drive and output the test signal received through the third pad 130-2. The second path control unit 143 may be configured to output the test signal provided through the second input unit 141, in response to the control signal CH_SEL. The second output unit 145 may be configured to transmit the output signal of the second path control unit 143 to the first pad 120.

Where the direct memory access signal (SEL_DMA) is enabled in the test mode, a test signal may be inputted through the second terminal group 16. Therefore, where the direct memory access signal (SEL_DMA) is enabled, after the signal applied through the third pad 130-2 is provided to the first pad 120 through the second signal transmission block 140, it may be outputted to the second pad 130-1 through the first signal transmission block 110-1. Even in this case, monitoring for the main input/output line (MIO) or the first terminal group 15 is possible according to the output path of the first signal transmission block 110-1.

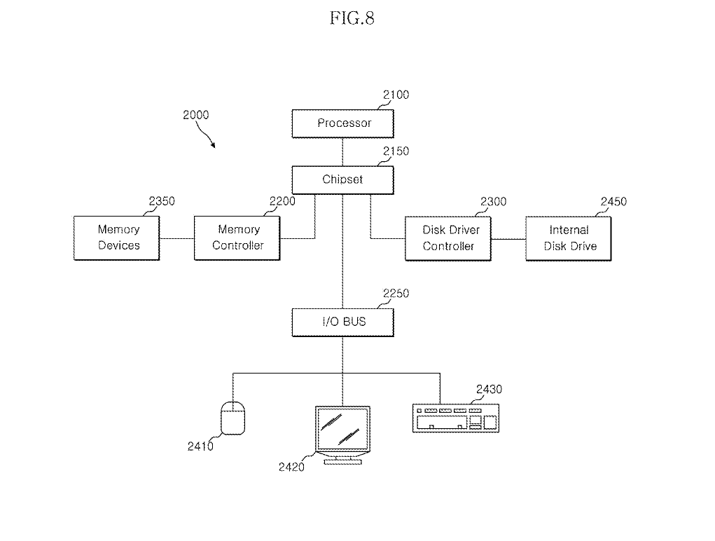

Referring to FIG. 7, a diagram showing embodiments of the first signal transmission block 110-1 and the second signal transmission block 140 shown in FIG. 6 is illustrated.

The configuration of the first signal transmission block 110-1 will be described below.

The first input unit 111-1 may be configured to include a buffer section 1111-1 which drives and outputs the test signal provided through the first pad 120.

The first path control unit 113-1 may be configured to include a dividing section 1131-1, a first path setting section 1133-1, and a second path setting section 1135-1.

The dividing section 1131-1 may be configured to provide the test signal provided from the first input unit 111-1, to the first path setting section 1133-1 or the second path setting section 1135-1 in response to the test mode signal TM.

The first path setting section 1133-1 may be configured to transmit the test signal provided from the dividing section 1131-1, to the first output line OUT1 in response to the test mode signal TM and the control signal CH_SEL. The second path setting section 1135-1 may be configured to transmit the test signal provided from the dividing section 1131-1, to the second output line OUT2 in response to the control signal CH_SEL.

One output line of the dividing section 1131-1, electrically coupled with the first path setting section 1133-1, is also electrically coupled with the transmission line 20 which is electrically coupled with the memory module 12. Therefore, when transmitting a test signal through the first path setting section 1133-1, it is possible to monitor the state of the main input/output line (MIO). In addition, by transmitting a test signal through the second path setting section 1135-1, it is possible to monitor the state of the first terminal group 15.

The first path setting section 1133-1 may be configured to include a determination part L11 which determines a test option in response to the test mode signal TM and the control signal CH_SEL. The first path setting section 1133-1 may also be configured to include a first output signal generation part L12 which generates a first test signal in response to the output signal of the determination part L11 and one output signal of the dividing section 1131-1. The first output signal generation part L12 also outputs the first test signal to the first output line OUT1. The test option may include a main input/output line (MIO) test option and a first terminal group test option.

The second path setting section 1135-1 may be configured to include a second output signal generation part L13 which generates a second test signal in response to the other output signal of the dividing section 1131-1 and the control signal CH_SEL. The second output signal generation part L13 also outputs the second test signal to the second output line OUT2.

The configuration of the second signal transmission block 140 will be described below.

The second input unit 141 may be configured to include a buffer section 1411 which drives and outputs the test signal provided through the third pad 130-2.

The second path control unit 143 may be configured to include a test signal generating section 1431 which generates and outputs a third test signal in response to the control signal CH_SEL and the output signal of the second input unit 141.

The second output unit 145 may be configured to include a driving section 1451 which drives and transmits the output signal of the second path control unit 143 to the first pad 120.

Where the direct memory access signal (SEL_DMA) is enabled and only the control signal CH_SEL is enabled, the test signal inputted through the third pad 130-2 is provided to the first signal transmission block 110-1 via the first pad 120 through the second signal transmission block 140. At this time, since only the control signal CH_SEL is in an enabled state, and the test mode signal TM is in a disabled state, the test signal is outputted to the second pad 130-1 through the second path setting section 1135-1 of the first signal transmission block 110-1. As a result, monitoring for the first terminal group 15 may be performed.

Where the direct memory access signal (SEL_DMA) is enabled and both the test mode signal TM and the control signal CH_SEL are enabled, the test signal inputted through the third pad 130-2 and provided to the first pad 120 through the second signal transmission block 140 is outputted to the second pad 130-1 through the first path setting section 1133-1 of the first signal transmission block 110-1. Accordingly, monitoring for the main input/output line (MIO) may be performed.

In an embodiment, through each of the test circuits 11A, 11-1 and 11-2 in the logic circuit block 11, it is possible to verify whether the signal provided from the controller 13 is precisely applied to the memory module 12. Therefore, the signal applied to the first terminal group 15 from the controller 13 may be outputted to an exterior. FIG. 7 also illustrates a selecting section 1151-1, a buffer section 1153-1, and an output unit 115-1.

Moreover, in a direct memory access mode, by applying a test signal through an external connection terminal and outputting the test signal through the first terminal group 15, it is possible for the state of the first terminal group 15 to be monitored.

Referring to FIG. 8, a system 2000 may include one or more processors 2100. The processor 2100 may be used individually or in combination with other processors. A chipset 2150 may be electrically coupled to the processor 2100. The chipset 2150 may be a communication pathway for signals between the processor 2100 and other components of the system 2000. Other components may include a memory controller 2200, an input/output (“I/O”) bus 2250, and a disk drive controller 2300. Depending on the configuration of the system 2000, any one of a number of different signals may be transmitted through the chipset 2150.

The memory controller 2200 may be electrically coupled to the chipset 2150. The memory controller 2200 can receive a request provided from the processor 2100 through the chipset 2150. The memory controller 2200 may be electrically coupled to one or more memory devices 2350. The memory device 2350 may include the stacked semiconductor memory apparatus 10 described above.

The chipset 2150 may also be electrically coupled to the I/O bus 2250. The I/O bus 2250 may serve as a communication pathway for signals from the chipset 2150 to I/O devices 2410, 2420 and 2430. The I/O devices 2410, 2420 and 2430 may include a mouse 2410, a video display 2420, or a keyboard 2430. The I/O bus 2250 may employ any one of a number of communications protocols to communicate with the I/O devices 2410, 2420, and 2430.

The disk drive controller 2300 may also be electrically coupled to the chipset 2150. The disk drive controller 2300 may serve as the communication pathway between the chipset 2150 and one or more internal disk drives 2450. The disk drive controller 2300 and the internal disk drive 2450 may communicate with each other or with the chipset 2150 using virtually any type of communication protocol.

While various embodiments have been described above, it will be understood to those skilled in the art that the embodiments described are by way of example only. Accordingly, the stacked semiconductor memory apparatus and the test circuit described should not be limited based on the described embodiments. Rather, the stacked semiconductor memory apparatus and the test circuit therefor described should only be limited in light of the claims that follow when taken in conjunction with the above description and accompanying figures.

What is claimed is:

1. A stacked semiconductor memory apparatus comprising:
a memory module including a plurality of memory chips; and
a logic circuit block with the memory module stacked thereon, configured to be electrically coupled with an interface substrate through a first terminal group and a second terminal group and to communicate with a controller, and to include a test circuit that receives a first test signal through the first terminal group from the controller and outputs the first test signal through the second terminal group in a test mode.

2. The stacked semiconductor memory apparatus according to claim 1, wherein the test circuit is configured to output a second test signal received through the second terminal group, to the second terminal group through the first terminal group, when a direct memory access signal is enabled in the test mode.

3. The stacked semiconductor memory apparatus according to claim 1, wherein the test circuit comprises:
a first pad electrically coupled with any one first terminal of the first terminal group;
a second pad electrically coupled with any one second terminal of the second terminal group; and
a signal transmission block electrically coupled between the first pad and the second pad, and configured to output the first test signal applied to the first pad, to the second pad through a first path or a second path in response to a test mode signal and a control signal.

4. The stacked semiconductor memory apparatus according to claim 3, wherein the signal transmission block comprises:
an input unit configured to drive the first test signal applied to the first pad;
a path control unit configured to transmit the first test signal provided from the input unit, to the first path or the second path in response to the test mode signal and the control signal; and
an output unit configured to select and output the first test signal transmitted to the first path or the second path.

5. The stacked semiconductor memory apparatus according to claim 4, wherein the path control unit comprises:
a dividing section configured to divide the first test signal provided from the input unit in response to the test mode signal;
a first path setting section configured to transmit one output signal of the dividing section to the first path in response to the test mode signal and the control signal; and
a second path setting section configured to transmit an other output signal of the dividing section to the second path in response to the control signal.

6. The stacked semiconductor memory apparatus according to claim 1, wherein the test circuit comprises:
a first pad electrically coupled with any one first terminal of the first terminal group;
a second pad electrically coupled with any one second terminal of the second terminal group;
a third pad electrically coupled with another second terminal of the second terminal group;
a first signal transmission block electrically coupled between the first pad and the second pad, and configured to output the first test signal applied to the first pad, to the second pad through a first path or a second path in response to a test mode signal and a control signal; and
a second signal transmission block electrically coupled between the third pad and the first pad, and configured to output a second test signal received through the third pad, to the second pad through the first pad and the first signal transmission block in response to the control signal when the direct memory access signal is enabled.

7. The stacked semiconductor memory apparatus according to claim 6, wherein the first signal transmission block comprises:
a first input unit configured to drive and output the first test signal applied to the first pad;
a first path control unit configured to transmit the first test signal provided from the first input unit, to the first path or the second path in response to the test mode signal and the control signal; and
a first output unit configured to select and output the first test signal transmitted to the first path or the second path.

8. The stacked semiconductor memory apparatus according to claim 7, wherein the first path control unit comprises:
a dividing section configured to divide the first test signal provided from the first input unit, in response to the test mode signal;
a first path setting section configured to transmit one output signal of the dividing section to the first path in response to the test mode signal and the control signal; and
a second path setting section configured to transmit an other output signal of the dividing section to the second path in response to the control signal.

9. The stacked semiconductor memory apparatus according to claim 6, wherein the second signal transmission block comprises:
a second input unit configured to drive and output the second test signal received through the third pad;
a second path control unit configured to output the second test signal provided through the second input unit, in response to the control signal; and
a second output unit configured to transmit an output signal of the second path control unit to the first pad.

10. A test circuit of a stacked semiconductor memory apparatus, comprising:
a first terminal group configured to be provided with a first test signal provided from a controller;
a first signal transmission block configured to transmit the first test signal applied to the first terminal group through a first path or a second path in response to a test mode signal and a control signal; and
a second terminal group configured to output the first test signal transmitted through the first path or the second path.

11. The test circuit according to claim 10, wherein the first terminal group is provided with the first test signal through an interface substrate.

12. The test circuit according to claim 10, wherein the second terminal group outputs the first test signal through the interface substrate to an external device.

13. The test circuit according to claim 10, wherein the first signal transmission block comprises:
a first input unit configured to drive and output the first test signal;
a first path control unit configured to transmit the first test signal provided from the first input unit to the first path or the second path in response to the test mode signal and the control signal; and
a first output unit configured to select and output the first test signal transmitted to the first path or the second path through the second terminal group.

14. The test circuit according to claim 13, wherein the first path control unit comprises:
a dividing section configured to divide the first test signal provided from the first input unit in response to the test mode signal;
a first path setting section configured to transmit one output signal of the dividing section to the first path in response to the test mode signal and the control signal; and
a second path setting section configured to transmit an other output signal of the dividing section to the second path in response to the control signal.

15. The test circuit according to claim 10, further comprising:
a second signal transmission block configured to output a second test signal to the second terminal group through the first terminal group in response to the control signal when a direct memory access signal is enabled.

16. The test circuit according to claim 15, wherein the second signal transmission block comprises:
a second input unit configured to drive and output the second test signal;
a second path control unit configured to output the second test signal provided through the second input unit, in response to the control signal; and
a second output unit configured to transmit an output signal of the second path control unit to the first pad.

17. A stacked semiconductor memory apparatus comprising:
a memory module including a plurality of stacked memory chips; and
a logic circuit block configured to be electrically coupled with an interface substrate through a first terminal group and a second terminal group and with the memory module stacked thereon and to perform a test for the memory module using the second terminal group.

18. The stacked semiconductor memory apparatus of claim 17, wherein the first terminal group is electrically coupled with a controller through the interface substrate and the second terminal group is electrically coupled with an external connection terminal group through the interface substrate.

19. The stacked semiconductor memory apparatus of claim 18, further comprising:
a test circuit configured to receive a signal from a controller in a test mode to output the signal to the external connection terminal group through the second terminal group and the interface substrate.

20. The stacked semiconductor memory apparatus of claim 18, further comprising:
a test circuit configured to receive a test signal from the external connection terminal group through the interface substrate and the second terminal group to transmit the test signal to the first terminal group and then output the test signal to an external connection terminal in the external connection terminal group when a direct memory access signal is enabled in a test mode.
